(19) United States
(12) Patent Application Publication
(10) Pub. No.: US 2010/0258431 A1
(43) Pub. Date: Oct. 14, 2010

(54) USE SPECIAL ION SOURCE APPARATUS AND IMPLANT WITH MOLECULAR IONS TO PROCESS HDD (HIGH DENSITY MAGNETIC DISKS) WITH PATTERNED MAGNETIC DOMAINS

(75) Inventors: Stephen Moffatt, St. Lawrence (JE); Majeed A. Foad, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/756,793

(22) Filed: Apr. 8, 2010

Related U.S. Application Data
(60) Provisional application No. 61/168,511, filed on Apr. 10, 2009.

(51) Int. Cl. C23C 14/46

(52) U.S. Cl. 204/192.11; 204/298.04

(57) ABSTRACT

A method and apparatus for manufacturing magnetic storage media is provided. A structural substrate is coated with a magnetically susceptible material, and a patterned resist layer is formed over the magnetically susceptible material. Atom groups are directed toward the substrate, penetrating the resist and implanting into the magnetically susceptible layer. Thick portions of the resist prevent implantation in some areas to form a pattern of magnetic properties on the substrate. Energy and composition of the atom groups, thickness and hardness of the resist, and lattice energy of the magnetically susceptible material may all be adjusted to yield desired fragmentation and implantation of the atom groups, including in some embodiments mere impact on the surface without implanting. A protective layer and a lubricating layer are formed over the patterned magnetically susceptible layer.

### CROSS-REFERENCE TO RELATED APPLICATIONS

This application claims benefit of U.S. Provisional Patent Application Ser. No. 61/168,511, filed Apr. 10, 2009, and incorporated herein by reference.

### FIELD

Embodiments of the invention relate to hard-disk drive media, and apparatus and methods for making hard-disk drive media. More specifically, embodiments of the invention relate to methods and apparatus for forming a patterned magnetic medium for a hard-disk drive.

### BACKGROUND

Hard-disk drives are the storage medium of choice for computers and related devices. They are found in most desktop and laptop computers, and may also be found in a number of consumer electronic devices, such as media recorders and players, and instruments for collecting and recording data. Hard-disk drives are also deployed in arrays for network storage.

Hard-disk drives store information magnetically. The disk in a hard-disk drive is configured with magnetic domains that are separately addressable by a magnetic head. The magnetic head moves into proximity with a magnetic domain and alters the magnetic properties of the domain to record information. To recover the recorded information, the magnetic head moves into proximity with the domain and detects the magnetic properties of the domain. The magnetic properties of the domain are generally interpreted as corresponding to one of two possible states, the “0” state and the “1” state. In this way, digital information may be recorded on the magnetic medium and recovered thereafter.

The magnetic medium in a hard-disk drive is generally a glass, composite glass/ceramic, or metal substrate, which is generally non-magnetic, with a magnetically susceptible material deposited thereon. The magnetically susceptible layer is generally deposited to form a pattern, such that the surface of the disk has areas of magnetic susceptibility interspersed with areas of magnetic inactivity. The non-magnetic substrate is usually topographically patterned, and the magnetically susceptible material deposited by spin-coating or electroplating. The disk may then be polished or planarized to expose the non-magnetic boundaries around the magnetic domains. In some cases, the magnetic material is deposited in a patterned way to form magnetic grains or dots separated by a non-magnetic area.

Such methods are expected to yield storage structures capable of supporting data density up to about 1 TB/in², with individual domains having dimensions as small as 20 nm. Where domains with different spin orientations meet there is a region referred to as a Bloch wall in which the spin orientation goes through a transition from the first orientation to the second. The width of this transition region limits the areal density of information storage because the Bloch wall occupies an increasing portion of the total magnetic domain.

To overcome the limit due to Bloch wall width in continuous magnetic thin films the domains can be physically separated by a non-magnetic region (which can be narrower than the width of a Bloch wall in a continuous magnetic thin film). Conventional approaches to creating discrete magnetic and non-magnetic areas on a medium have focused on forming single bit magnetic domains that are completely separate from each other, either by depositing the magnetic domains as separate islands or by removing material from a continuous magnetic film to physically separate the magnetic domains. A substrate may be masked and patterned, and a magnetic material deposited over exposed portions, or the magnetic material may be deposited before masking and patterning, and then etched away in exposed portions. In either case, the topography of the substrate is altered by the residual pattern of the magnetic regions. Because the read-write head of a typical hard-disk drive may fly as close as 2 nm from the surface of the disk, these topographic alterations can become limiting. Thus, there is a need for a process or method of patterning magnetic media that has high resolution and does not alter the topography of the media, and an apparatus for performing the process or method efficiently for high volume manufacturing.

### SUMMARY

Embodiments of the invention provide a method of forming a magnetic recording medium, comprising modifying the magnetic properties of portions of a magnetically susceptible layer of the magnetic recording medium by exposing those portions to atom groups directed toward the substrate with energy selected to modify the magnetic properties without substantially modifying the shape of the substrate surface.

Other embodiments provide a method of treating a substrate, comprising forming a magnetically susceptible layer on a structural substrate, forming a patterned layer over the magnetically susceptible layer to identify treatment zones and masked zones, directing atom groups toward the substrate with energy sufficient to penetrate the patterned layer and implant into the treatment zones of the magnetically susceptible layer, forming a protective layer over the substrate, and forming a lubricating layer over the surface.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a flow diagram summarizing a method according to one embodiment.

FIGS. 1B-1D are schematic side views of a substrate at various stages of the method of FIG. 1A.

FIG. 2A is a flow diagram summarizing a method according to another embodiment.

FIGS. 2B-2D are schematic side views of a substrate at various stages of the method of FIG. 2A.

FIG. 3A is a flow diagram summarizing a process according to an embodiment.

FIGS. 3B-3I are schematic side views showing various substrates at different stages of the process of FIG. 3A.

FIG. 4 is a schematic cross-sectional view of an apparatus 400 according to an embodiment of the invention.

FIG. 5A is a perspective view of a substrate carrier according to one embodiment.

FIG. 5B is a cross-sectional view of a substrate carrier according to another embodiment.

FIG. 6A is a flow diagram summarizing a method according to an embodiment.

FIGS. 6B-6F are schematic side views showing a substrate at different stages of the method of FIG. 6A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally provide apparatus and methods for processing magnetic media substrates for hard disk drives. The apparatus and methods modify the magnetic properties of the substrate by applying energy to the substrate in a patterned way to create magnetic domains with different properties detectable and changeable by a magnetic head. The magnetic domains are separately addressable by a magnetic head held in proximity to the substrate surface, enabling the magnetic head to detect and affect the magnetic properties of an individual magnetic domain. Embodiments of the invention create magnetic domains having a dimension less than about 25 nm while preserving the topography of the substrate.

The substrates used are generally metal or glass, and may be metal alloys or composite glass substances such as glass/ceramic blends. The substrates are generally coated with a magnetically susceptible material that provides a medium for magnetic patterning. The magnetically susceptible material may be formed in multiple layers, each layer having the same or different composition. In one embodiment, a first layer of soft magnetic material, such as iron or and iron/nickel alloy, is formed over the base substrate, and a second layer of magnetic material, such as a cobalt/nickel/platinum alloy, is formed over the first layer. These layers may be formed by any suitable method known to the art, such as physical vapor deposition, or sputtering, chemical vapor deposition, plasma-enhanced chemical vapor deposition, spin-coating, plating by electrochemical or electroless means, and the like.

Following formation of a magnetic pattern in the magnetically susceptible material, described in more detail below, a protective layer is formed over the magnetically susceptible layer to prevent contact between the magnetic head and the magnetic medium. The protective layer is preferably magnetically inactive, and in some embodiments comprises carbon, such as amorphous or diamond-like carbon, or carbon nitride. The protective layer is also generally very thin, such as less than about 10 nm in thickness.

A lubricating layer may be formed over the protective layer to protect the magnetic head in the event of contact between the head and the substrate. The lubricating layer may be a lubricious polymer, such as a fluoropolymer, and may be deposited by any convenient method. The lubricating layer will also generally be thin, such as less than about 50 nm in thickness.

Embodiments of the invention provide methods and apparatus for establishing a magnetic pattern in one or more surfaces of a hard disk medium through a physical patterning process. A pattern template is coated with a mask material, and the template applied to the substrate to be patterned. The mask material is thus applied to the substrate according to the pattern of the template. A very detailed pattern having features of dimension less than about 25 nm may be imprinted on the substrate in this way. The mask may leave portions of the substrate completely exposed, or may cover some portions with a thin mask layer and others with a thick mask layer. The portions of the substrate that remain exposed, or covered with a thin mask layer, are essentially unmasked, while the other portions are masked. Unmasked portions of the substrate may then be exposed to energy to alter the magnetic properties of the unmasked portions. Upon removal of the mask, the substrate is left with its original topography, but with a very fine pattern of magnetic and non-magnetic domains capable of supporting storage densities in excess of 1 Tb/in².

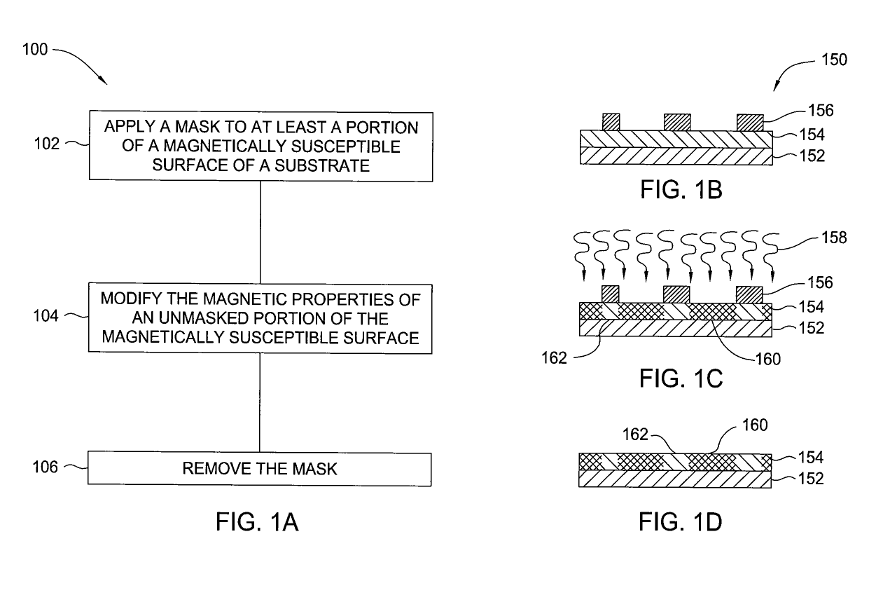

FIG. 1A is a flow diagram summarizing a method 100 according to one embodiment of the invention. FIGS. 1B-1D are schematic cross-sectional views of a substrate 150 at various stages of the process of FIG. 1A. The substrate 150 has a base layer 152 and a magnetically susceptible layer 154. The base layer 152 is generally a structurally strong material such as metal, glass, ceramic, or a combination thereof. Many substrates commonly feature an aluminum or glass base layer, but other embodiments may feature carbon composite materials. The base layer 152 provides structural strength and good adhesion to the magnetically susceptible layer 154, and is generally magnetically impermeable with diamagnetic, or only very weak paramagnetic, properties. For example, in some embodiments, the magnetic susceptibility of the base layer is below about 10⁻⁴ (the magnetic susceptibility of aluminum is about 1.2×10⁻⁵).

The magnetically susceptible layer 154 is generally formed from one or more ferromagnetic materials. In some embodiments, the layer 154 comprises a plurality of layers having the same or different composition. In one embodiment, the layer 154 comprises a first layer and a second layer, wherein the first layer is a soft magnetic material, which is generally defined as a material with low magnetic coercivity, and the second layer has higher coercivity than the first layer. In some embodiments, the first layer may comprise iron, nickel, platinum, or combinations thereof. In some embodiments, the first layer may comprise a plurality of sub-layers having the same or different compositions. The second layer may also comprise a variety of materials, such as cobalt, chromium, platinum, tantalum, iron, terbium, gadolinium, or combinations thereof. The second layer may also comprise a plurality of sub-layers having the same or different compositions. In one embodiment, the magnetically susceptible layer 154 comprises a first layer of iron or iron/nickel alloy having a thickness between about 100 nm and about 1,000 nm (1 μm) and a second layer comprising two sub-layers, each having a thickness between about 30 nm and about 70 nm, such as about 50 nm, and each comprising chromium, cobalt, and platinum.

The magnetic surface is patterned to form domains of varying magnetic activity. To create the domain pattern, a mask material 156 is applied to the substrate 150 at 102. The mask material 156 generally comprises a material that can be readily removed without altering the magnetically susceptible layer 154 in any way, or a material that will not adversely affect the device properties if it is not removed. For example, in many embodiments, the mask material is soluble in a solvent liquid, such as water or hydrocarbon. In some embodiments, the mask is applied to the substrate as a curable liquid, patterned by physical imprint with a template, and cured by heating or UV exposure. In other embodiments, the mask is applied to the template and at least partially cured before applying the coated template to the substrate. The mask material 156 is generally also resistant to degradation by incident energy or energetic ions. In some embodiments, the mask material 156 is a curable material, such as an epoxy or thermoplastic polymer, that will flow prior to being cured and will provide some resistance to energetic processes after curing. The mask material defines masked and unmasked portions of the magnetically susceptible layer 154.

At 104, the magnetic properties of the unmasked portions of the magnetically susceptible layer 154 are modified. Energy 158 is directed toward the substrate 150, and impinges on the exposed unmasked portions of the magnetically susceptible layer 154. Exposing magnetic materials to energy will generally begin to disrupt and change the magnetic properties when the energy reaches sufficient intensity to stimulate thermal motion of the atoms in the material. Energy above a certain threshold will randomize the spin direction of the atoms, reducing or eliminating the magnetic properties of the material. In some embodiments, the magnetism or the magnetic susceptibility of the magnetically susceptible layer 154 may be reduced or eliminated by exposure to the energy 158. Magnetic susceptibility is the ease with which a material will acquire magnetism when exposed to a magnetic field. Modification of the unmasked portions of the magnetically susceptible layer 154 creates a pattern of domains defined by the unmodified zones 162 and the modified zones 160. The pattern may be recognized as domains of magnetic and non-magnetic material, domains of high and low magnetic field, or domains of high and low magnetic susceptibility. The mask 156 is then removed at 106, leaving the substrate with a magnetically susceptible layer 154 having a pattern of domains defined by high activity zones 162 and low activity zones 160. The resulting substrate 150 has substantially the same topography as it had before processing.

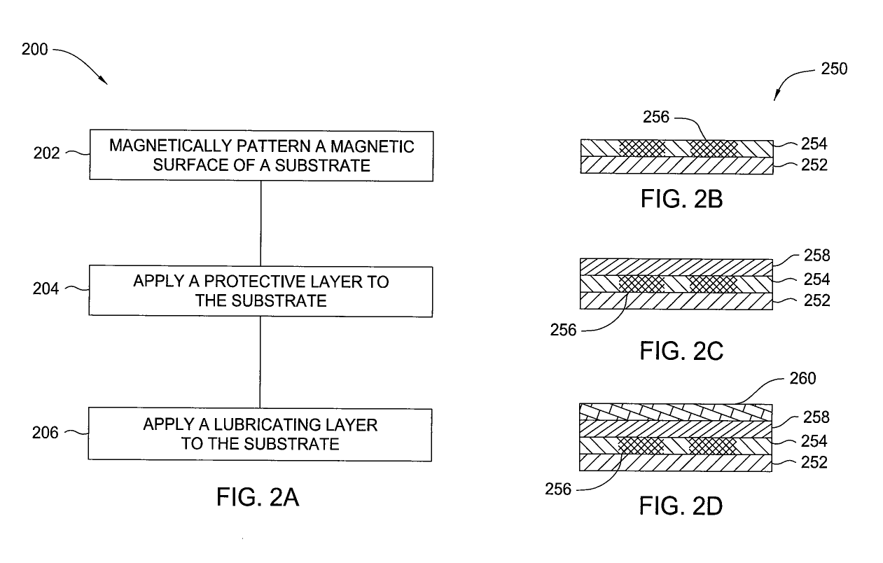

FIG. 2A is a flow diagram summarizing a method 200 according to another embodiment of the invention. FIGS. 2B-2D are schematic side-views of a substrate 250 at various stages of the method of FIG. 2A. At 202, a magnetic surface of a substrate is patterned into regions having different magnetic properties in a process similar to that described in connection with FIGS. 1A-1D. FIG. 2B shows the substrate 250 having a base layer 252 and a magnetic layer 254. The base layer 252 and magnetic layer 254 may have properties similar to the base layer 152 and magnetically susceptible layer 154 described above. The patterned areas 256 of the magnetic surface 254 have different magnetic properties from the unpatterned areas. For example, the patterned areas 256 may be substantially demagnetized, or their magnetism or magnetic susceptibility may have been reduced or altered.

At 204, a protective layer 258 is formed on the substrate over the magnetic layer. The protective layer 258 prevents interaction of the magnetic surface with any materials that might degrade its properties, such as oxygen or moisture. The protective layer 258 may also be a sealing layer in some embodiments. In some embodiments, the protective layer 258 may comprise carbon, may comprise carbon and nitrogen, may be a carbon and nitrogen containing layer, may be an amorphous carbon layer, or may be a carbon nitride layer. In other embodiments, the protective layer 258 may be a polymer, which may comprise carbon. In some embodiments, the protective layer 258 may be a plastic or thermoplastic material. The protective layer is generally deposited in a low temperature process to avoid altering the magnetic properties of the magnetic layer 254.

At 206, a lubricating layer 260 is formed over the substrate. The lubricating layer 260 provides protection for a magnetic device (not shown) configured to detect and change the magnetic properties of regions on the magnetic surface 254 of the substrate 250. In the event of contact between the magnetic device and the substrate surface, the lubricating layer 260 will minimize frictional forces on the magnetic device that may damage the device. In some embodiments, the lubricating layer 260 may be a polymer, a carbon containing polymer, a fluorine containing polymer, a fluorine and carbon containing polymer, a fluoropolymer, a crystalline layer, or a diamond-like carbon layer. The lubricating layer 260 is generally also deposited in a low temperature process.

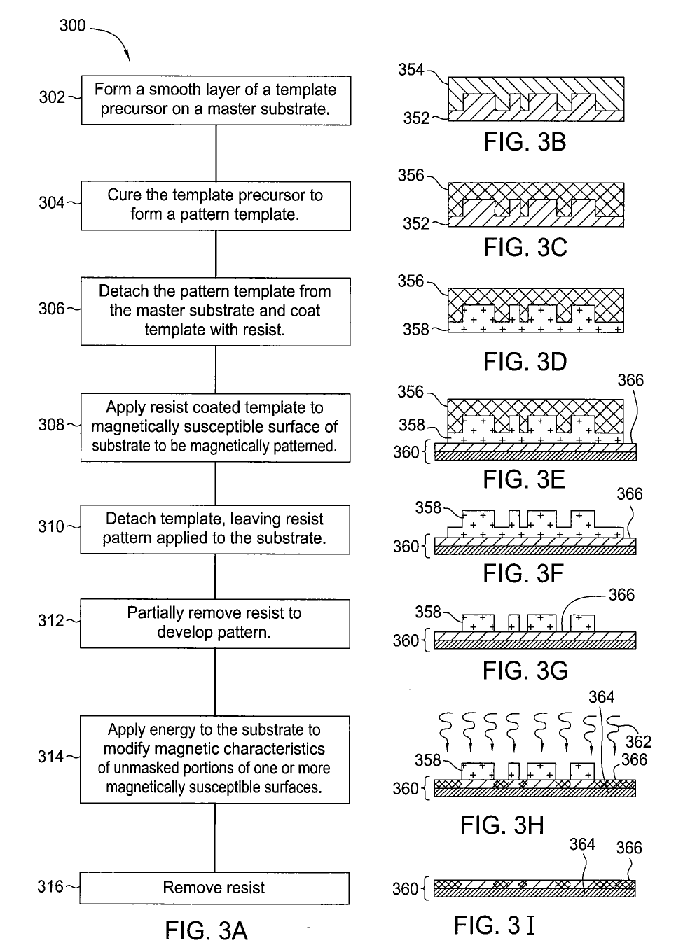

FIG. 3A is a flow diagram summarizing a method 300 according to another embodiment of the invention. FIGS. 3B-3I show various articles used in the method 300 at various stages of the method 300. At 302, a template precursor material 354 is applied to a master substrate 352 to acquire a pattern. The master substrate 352 expresses the master pattern to be developed on successive substrates according to the method 300. The master substrate 352 may comprise any durable material, such as metal, glass, or ceramic, and may be invested with an original pattern through any suitable process, such as any patterning process, for example by a deposition or etching process, or a combination thereof. In one embodiment, the master substrate may be patterned by an e-beam process. The e-beam process may comprise direct engraving with an electron beam or electron beam lithography followed by etching. In another embodiment, UV photolithography may be used to pattern the master substrate 352. The template precursor material 354 may be applied to the master substrate 352 as a gas or a liquid, and is preferably applied to form a smooth layer over the master substrate 352 using any suitable process, such as spin coating, die coating, or vapor deposition. The surface of the template precursor material 354 that interfaces with the master substrate 352 thus acquires the pattern recorded in the master substrate 352. In some embodiments, the template precursor material may be polyvinyl alcohol (PVA). In other embodiments, the template precursor material may be a curable polymer, such as an elastomer.

At 304, the template precursor 354 may be cured to form a pattern template 356. The pattern template 356 will generally be a flexible solid material. The curing process may comprise heating, drying, or UV treating the template precursor 354. After curing, the pattern template 356 will preferably have enough mechanical strength to be disengaged from the master substrate 352 without damaging or permanently distorting the pattern template 356. For example, liquid polyvinyl alcohol may be applied to a master substrate to a thickness of between about 10 nm and about 1,000 nm, such as between about 50 nm and about 200 nm, for example about 100 nm, by spin-coating, die-coating, or extrusion-coating, and then cured at a temperature between about 50° C. and about 300° C., such as about 100° C., for about 1 to 5 minutes to solidify.

At 306, the pattern template 356 is detached from the master substrate 352, and is coated with a resist material 358. The resist material 358 may be applied to the pattern template 356 as a liquid or a gas using any suitable process, such as spin coating, die coating, ink jet printing, or vapor deposition. The resist material 358 is applied to form a smooth layer over the pattern template 356. The resist layer is generally thin, such as between about 10 nm and about 100 nm, for example about 60 nm, thick.

At 308, the pattern template 356 with the resist coating 358 is applied to a magnetically susceptible layer 366 of a substrate 360 to be magnetically patterned. This is usually done through a process of physical contact between the resist coating 358 and the magnetically susceptible layer 366, and may require a precision alignment process. In some embodiments, a precision alignment is accomplished through visual or automated alignment of marks on the substrate 360, or device holding the substrate, and the pattern template 356. An optional curing process may be employed after physical contact is made between the resist coating 358 and the magnetically susceptible layer 366, and may comprise heating, drying, or exposure to electromagnetic energy. The curing process may facilitate the resist coating 358 adhering to the magnetically susceptible layer 366 with more force than it adheres to the pattern template 356.

At 310 the pattern template 356 is detached from the resist coating 358, leaving the resist coating 358, with pattern acquired from the pattern template 356, adhered to the substrate 360. At 312, the pattern is developed by removing a portion of the resist coating 358, exposing the magnetically susceptible layer 366 underneath. In alternate embodiments, the resist coating may be used as applied without exposing any underlying surface, because subsequent processing may be configured to penetrate the thinner portions of the resist layer while being successfully obstructed by the thicker portions of the resist layer. Thus, removing a portion of the resist coating 358 at 312 is optional. In most embodiments, the resist layer will generally be between about 30 nm and about 100 nm thick, such as between about 50 nm and about 70 nm thick. In many embodiments, the resist layer will have thick and thin portions, the thin portions calibrated to admit incident energy or particles, and the thick portions calibrated to block incident energy or particles. The thick portions therefore mask areas of the substrate surface they cover, whereas the thin portions expose areas they cover. In some embodiments, the resist layer will have thick portions having a first thickness and thin portions having a second thickness, wherein a ratio of the first thickness to the second thickness is between about 1.3 and about 1.8, or between about 1.4 and about 1.7, such as between about 1.5 and about 1.6

At 314, energy 362 is applied to the substrate 360 according to any of the methods described above in connection with FIGS. 1A-1D and 2A-2D to modify the magnetic properties of unmasked portions 364 of the magnetically susceptible layer 366. Although the energy 362 is shown modifying the unmasked portions 364 through the entire thickness of the magnetically susceptible layer 366, it may be advantageous in some embodiments to modify only a portion of the layer near the surface of the magnetically susceptible layer 366. For example, deeper modification may be expected to lead to sharper differentiation of magnetic properties between the domains. Additionally, however, modification of properties may not proceed directly perpendicular to the surface of the layer 366. As energy 362 impinges on the surface of the layer 366, its effects may travel laterally through the layer 366 to some extent, modifying the magnetic properties of domains not directly below the locus of impingement. This lateral spreading will degrade magnetic properties at the margins of the masked portions, reducing clarity of boundaries between the domains. For this reason, the desired depth of modification depends on the ratio of layer thickness to width or dimension of the unmasked portion being modified. At higher ratios of film thickness to width of unmasked portion, the desired depth of modification as a fraction of the total film thickness will be smaller.

After patterning at 314, the resist material is removed at 316, leaving the substrate with magnetically susceptible layer 366 having a pattern of magnetic properties. The resist material may be removed by etching with a chemistry that does not react with the underlying magnetic materials, such as a dry cleaning or ashing process, or by dissolving in a liquid solvent such as DMSO. In one example, Due to the absence of permanent deposition on, or etching of, the magnetically susceptible layer 366, its topography after patterning is substantially identical to its topography before patterning.

The methods 100, 200, and 300 of FIGS. 1A-1D, 2A-2D, and 3A-3I feature patterning of a substrate surface into regions having different magnetic properties. In one embodiment, the substrate is exposed to atom groups directed toward the substrate surface. The groups may be molecular ions, cluster ions, neutral molecules, allotropes, radicals, or other close groupings of atoms delivered by a device, such as an implanter, configured to direct charged or neutral particles toward a workpiece. Molecules may be ionized by a process similar to that used to ionize atoms, exposure to an electric field or charge exchange medium to remove one or more electrons from each molecule. The ions so formed may be mass-selected, accelerated to a desired energy, and directed toward a substrate. Cluster ions may be formed by exposing a nanocondensate, formed by adiabatic expansion of a gas into a vacuum, to a charge exchange medium such as an electron gas or plasma. Neutrals may be formed by exposing ions formed by any of the processes above to a neutralizing charge-exchange medium. Cluster ions or molecular ions are useful in this regard because high energy may be delivered to a substrate at low current, reducing dispersion problems commonly encountered with ion beams. Boranes such as decaborane (B₁₀H₁₄), octadecaborane (B₁₈H₂₂), and higher (such as B₂₀, B₃₀, B₄₀) are useful for molecular ion implantation. Likewise, other hydrides such as silanes, germanes, and hydrocarbons may be used. In other embodiments, atom groups of carbon and boron, such as carboranes, carborynes, and dicarbollide anions, may be used. Cluster ions, such as clusters of neon, argon, or xenon atoms, may be formed by adiabatic expansion of mixed gases having virtually unlimited variation in composition. Clusters having up to 10,000 atoms, such as between about 2,000 and about 10,000 atoms, for example 3,000 atoms or 4,000 atoms, may be formed in this manner. In some embodiments, large ions may be formed from large atom groups, which may be clusters, such as nanocondensates, having at least 10 atoms, or molecules having at least 100 atoms. The ions are generally accelerated to a desired energy by exposure to an electric field. Once set in motion, they may be neutralized by exposure to a charge-exchange medium, for example an inert gas such as argon or helium. Generally, the ions may comprise elements from the group consisting of boron, hydrogen, nitrogen, oxygen, carbon, silicon, germanium, neon, argon, xenon, and fluorine.

The charged or neutral atom groups substantially amorphize the substrate surface if the impact is sufficiently energetic. The groups carry the combined kinetic energy of all the atoms in the group, so large groups may create impact craters as they implant. In some embodiments, the atom groups, which may be ions or neutrals, have average energy less than about 50 keV. In other embodiments, the groups have average energy less than about 20 keV. The atoms in a group may have average energy less than about 5 keV, such as less than about 2 keV.

Groups generally fragment as they implant due to shear forces with the substrate matrix. Fragments continue travelling into the surface, but frequently acquire lateral momentum due to interaction with the substrate matrix. Depending on the cohesive energy of bonds between atoms in the group and the lattice energy of the matrix, more or less fragmentation may occur. Because surface smoothness tolerances for hard-drive substrate are on the order of 2 nm or less, texture imparted by amorphization of the substrate surface during bombardment by atom groups may be counterproductive in some embodiments. For this reason, some embodiments may benefit from careful control of the fragmentation pattern of groups. If large groups are used, but large craters must be avoided, pre-fragmentation to some extent may be desirable. Alternately, if deeper implantation is desired, groups having higher cohesion compared to the lattice energy of the substrate may be selected, resulting in less fragmentation upon impact.

Fragmentation may be expressed numerically as F=1−M_{f}/M_{c}, where M_{f} is the average mass of the implanted fragments and M_{c} is the average mass of the groups. Octadecaborane, for example, will generally implant with fragmentation between about 95% and about 99%, depending on the implant energy and the lattice energy of the substrate, breaking down to fragments mostly comprising boron atoms, with a few two-atom or three-atom implanted clusters possible. Higher energy implant for a given group will result in higher fragmentation, and vice-versa.

In some cases, low incident kinetic energy may cause fragmentation without implantation. Depending on the thickness of the patterned layer, a group may have enough energy to penetrate to the substrate surface and fragment without penetrating the substrate. If the group impacts the resist with enough energy to overcome the cohesion of the group, it may fragment as it passes through the resist material. If the fragments arrive at the substrate surface with energy less than that required to overcome the lattice energy of the substrate, the fragments will deposit on the surface. Fragments depositing on the surface may still carry enough energy to disrupt the order of magnetic domains at, or just below, the surface of the substrate, which may be a useful embodiment for very thin magnetic layers, such as less than about 5 nm thick.

In embodiments wherein atom groups are directed toward the substrate with energy selected to penetrate portions of the patterned resist and reach the substrate surface without penetrating the substrate surface, a diffusion process may be used to encourage the deposited atoms to migrate into the surface. In such embodiments, portions of the resist layer may contain quantities of the deposited material that did not reach the substrate surface. It may be useful, in some embodiments, to remove the patterned resist layer prior to diffusion to avoid over-dosing the substrate surface. Diffusion is generally encouraged by applying heat to the substrate and the deposited layer to raise the temperature of the substrate above a diffusion temperature, which is a temperature above which substantial diffusion occurs into the substrate. The temperature used will generally be below the Curie Temperature of the substrate. Using an absolute temperature scale, a temperature less than about 90% of the Curie Temperature may encourage diffusion without substantially affecting the magnetic properties of regions of the substrate surface not undergoing diffusion.

Fragmentation may be encouraged within the resist layer by including heavy components in the resist layer, as described below. Selecting a harder resist layer allows treatment with relatively high energy atom groups, such as groups wherein the average kinetic energy of the atoms in the groups is about 2 keV or higher, which fragment heavily before reaching the substrate. In some embodiments, the degree of fragmentation is influenced by selection of resist hardness and impact energy of the atom groups with the resist. Fragmentation may be substantially complete before the fragments pass through the resist in such embodiments. Conversely, such a resist may be used to achieve a desired fragmentation in the resist prior to impact with the substrate. The fragments may still carry enough energy to implant substantially into the substrate surface without generating an impact crater and without further fragmenting. Additionally, fragmentation prior to striking the resist layer may be encouraged by passing the atom groups through an inert gas to cause collisions between the atom groups and the inert gas. Pre-fragmentation prior to impact with the resist and through the resist material will generally only achieve up to about 75% fragmentation, with further fragmentation on impact with the substrate.

In some embodiments, masking may be enhanced by formation of a hard mask layer under the resist layer. The hard mask layer may be formed by any suitable process, including CVD and PECVD, and may comprise silicon, carbon, oxygen, and nitrogen. In some embodiments, an amorphous carbon hard mask may be used to enhance masking, and may be easily removed thereafter. Use of a hard mask in addition to the patterned resist may enhance selectivity of group penetration by increasing the stopping capability of thick resist areas, so that thinner resist layers may be used for patterning. The thinner resist layers allow lower energy group impact, which may be useful for modifying thinner magnetically susceptible layers.

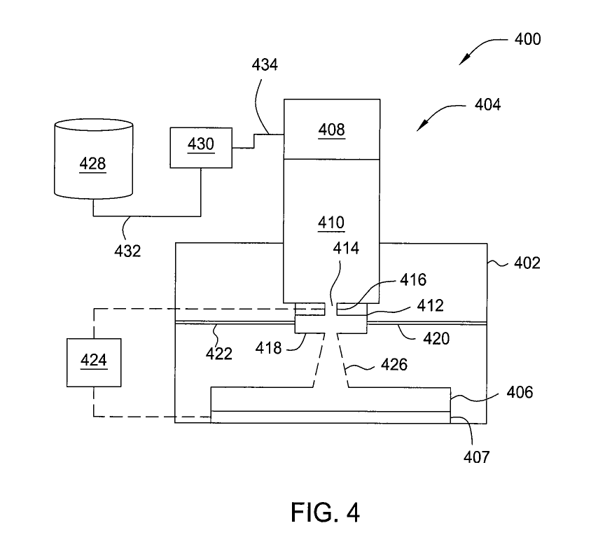

FIG. 4 is a schematic cross-sectional view of an apparatus 400 according to an embodiment of the invention. The apparatus 400 comprises a chamber 402 for processing one or more substrates, a beam column 404 for generating energetic particles, and a substrate support 406 for positioning one or more substrates to be treated.

The beam column 404 comprises an ion generator 408 and an accelerator 410 for moving the ions into the chamber 400. Ions move from the generator 408 through the accelerator and exit through opening 414 into an optional neutralizer 412. The neutralizer 412 may be used to convert the ions into neutrally charged particles, if desired. The beam column 404 may be an ion beam generator for generating large ions from large atom groups provided to the ion generator. In one aspect, the ion generator of the beam column or ion beam generator 404 applies energy to large atom groups, the energy being selected to ionize the large atom groups into large ions without causing excessive fragmentation. For example, in one embodiment, the ion generator forms large ions from large atom groups with less than 20% loss in number of atoms.

The neutralizer 412 may comprise a gas chamber 418 and a focusing member 416 configured to focus the beam prior to neutralization so that the neutralized beam has the desired diameter upon impacting the one or more substrates. A neutralizing gas is provided to the gas chamber 418 through conduit 420 and absorbs electrical charge from the ion beam entering from the focusing member 416. The charged gas exits the gas chamber 418 through conduit 422. The beam focusing member 416 may also have electromagnetics for diverting the beam direction in one or two dimensions to impact different locations on the one or more substrates.

The beam 426 produced by the beam column 404, with or without the neutralizer 412, impinges one or more substrates disposed on the substrate support 406. For embodiments featuring more than one substrate, the substrates may be disposed on a carrier (not shown in FIG. 4), which in turn is positioned on the substrate support. The beam 426 is directed toward all portions of all substrates disposed on the substrate support 406 by moving the substrates with respect to the beam 426. The substrate support 406 may be mounted on a moveable stage 407, which may be moveable in one or two directions. A stage 407 moveable in only one direction may be coupled with a focusing member 416 with the capability to divert the beam 426 in an orthogonal direction to reach all areas of the substrates. A stage 407 moveable in two directions may move the substrates with respect to the beam 426 such that all areas of the substrates may be treated.

Motion of the substrate support 406 on the moveable stage 407 may be controlled by a controller 424 capable of positioning the substrate support at any desired location along its range of motion. If the stage 407 is capable of motion in only one direction and the beam column 404 comprises a focus member 416 capable of diverting the beam 426 in a direction orthogonal to the travel direction of the stage 406, the controller 424 may be configured to control both the stage and the beam.

The beam column 404 of FIG. 4 may be configured to develop the beam 426 into a ribbon having unequal length and width. Electromagnetics may be disposed in the focus member 416 for elongating the shape of the beam, or even splitting the beam into multiple parallel beams, to form such a ribbon. For a ribbon beam having length substantially equal to a dimension of the substrate or carrier, the stage 407 may move the substrate or carrier in one direction only to accomplish exposure to the beam ribbon. Thus, a ribbon beam column coupled with a unidirectional stage 407 will suffice for exposing all areas of the one or more substrates disposed on the support 406.

Atom groups are provided to the beam column 404 by one or more sources 428. The one or more sources 428 may contain liquid or vapor components that may be blended into one or more precursor gas blends to be provided to the ion generator 408, or may be provided separately to the ion generator 408 through separate pathways. In some embodiments, the one or more sources 428 comprise a liquid ampoule. One or more atom group generators 430 renders the atom groups in a state ready to be ionized by the ion generator 408. The one or more atom group generators 430 may be selected from the group consisting of vaporizer, a cluster generator, or a nanocondensate generator.

In embodiments wherein a vaporizer is used as at least one of the one or more atom group generators 430, molecules are provided to the vaporizer as a liquid through one or more pathways 432 coupling the one or more sources 428 to the vaporizer, of which there may also be a plurality. The vaporizer may be internally heated, such as with a heating loop, or externally heated, such as with a resistive or conductive heat jacket. The vaporized atom groups move through one or more pathways 434 coupling the one or more atom group generators 430 to the beam column 404 and ion generator 408.

The one or more pathways 434 may be pipe or tubing adapted for vapor service, and may have requisite valving and control elements. The one or more pathways 434 may be heated by any convenient means, such as resistive or conductive heat jacketing, and may be thermally insulated to avoid heat loss and condensation. The one or more pathways 434 may likewise be lined to prevent condensation, nucleation, or solidification. Such linings may have non-stick, non-reactive, impact absorbent, or low friction properties, or any combination thereof. In embodiments wherein a nanocondensate generator is used as at least one of the one or more atom group generators 430, the one or more pathways 434 conducting nanocondensates to the beam column 404 may be designed for low wall impact and low friction to avoid shearing nanocondensates, which may be agglomerated by weak attractive forces. In some embodiments, the one or more pathways 430 carrying nanocondensates may be straight, or designed with long-radius turns, and may feature bellows valves, or other valves and control elements designed for low impact and low friction.

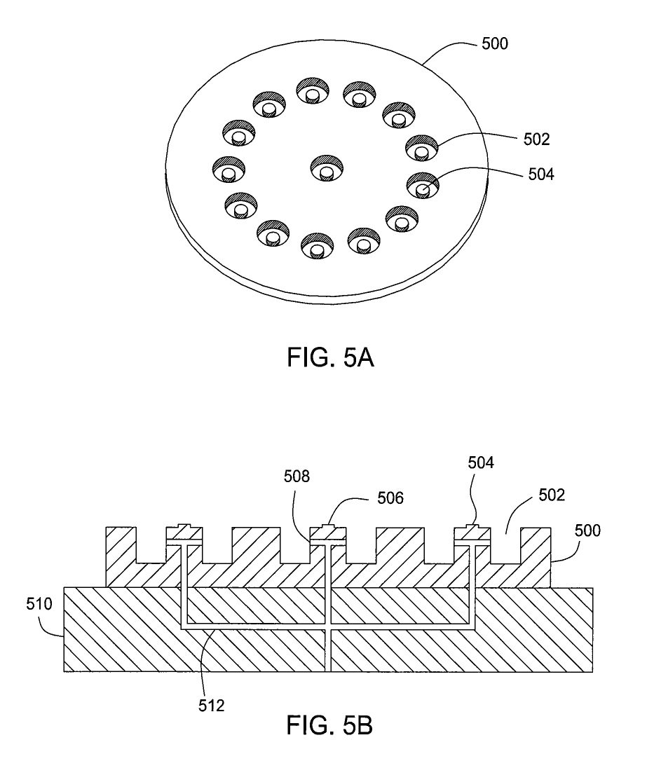

FIGS. 5A and 5B are schematic illustrations of a substrate carrier 500 according to an embodiment of the invention. FIG. 5A shows the substrate carrier 500 in a perspective view, and FIG. 5B shows the substrate carrier 500 coupled to a support 510. The substrate carrier 500 has a plurality of substrate sites 502 for disposing substrates thereon. In the embodiment of FIG. 5A, the substrate sites 502 are illustrated as recessed areas of the carrier 500. Each substrate site 502 has a contact portion 504 for stabilizing the substrate. The substrate will generally rest on the contact portion 504, and extend outward toward the rim of the recessed site 502, creating a cavity beneath the substrate.

FIG. 5B illustrates the carrier 500 in cross-section coupled to a support 510. The contact portion 504 has an extension 506 for mating with an opening at the center of a substrate. The carrier 500 also has a plurality of conduits 508 disposed through the contact portions 504. The conduits 508 are in fluid communication with conduits 512 similarly disposed in the support 510. The conduits 512 and 508 provide means for apply a thermal control medium, such as a heating or cooling medium, to the cavity beneath each substrate disposed in a substrate site 502. For processes described herein which may require cooling of substrates, a cooling gas may be provided to the back side of the substrates through the conduits 512 and 508. In one embodiment, modifying the magnetic surface of the substrates may raise their temperature to a level sufficient to degrade the resist material or threaten the integrity of the magnetic layer. In such an embodiment, the substrate may be cooled during processing by applying a cool non-reactive gas, such as helium, argon, hydrogen, or nitrogen, to the substrate.

In an alternate embodiment of a substrate carrier, the substrate sites may be projections above the otherwise flat surface of the carrier. The projections may be shaped to mate with openings in the substrates such that the substrates are held above the flat surface of the carrier. The projections may comprise conduits similar to those described above for thermal control of the back side of each substrate.

In the substrate carrier of FIG. 5B, the conduits 508 are illustrated as projecting outward from the contact portion 504 at a 90° angle from a major axis of the contact portion 504. In alternate embodiments, the conduits 508 may be fitted with nozzles to shape or direct the flow of a thermal control medium in any desired way. For example, nozzles may divert the thermal control medium at an upward angle toward the substrate. In an alternate embodiment, the conduits 504 may be formed having an upward angle to direct a thermal control medium toward the substrate. In many embodiments, a heating or cooling gas may be used for thermal control with the substrate carrier of FIG. 5B.

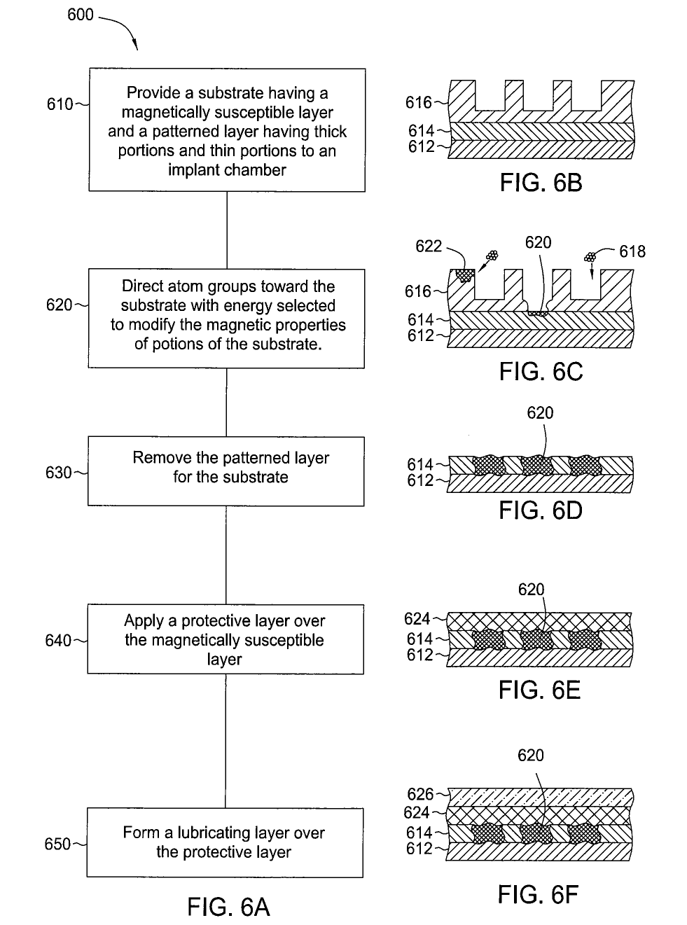

FIG. 6A is a flow diagram summarizing a method 600 according to an embodiment of the invention. FIGS. 6B-6F are schematic side-views of a substrate at various stages of the method 600. The method 600 may be used to create a pattern of magnetic susceptibility in a magnetic layer of a substrate. At 610 a substrate having a magnetically susceptible layer and a patterned layer, wherein the patterned layer has thick portions and thin portions, is provided to an implant chamber. The substrate and magnetically susceptible layer may be formed according to any of the embodiments described elsewhere herein. FIG. 6B shows an exemplary substrate with a structural layer 612 to support a magnetically susceptible layer 614. A patterned layer 616, having thick portions 632 and thin portions 634, is formed over the magnetically susceptible layer 614.

At 620, atom groups are directed toward the substrate. The atom groups have impact energy selected to penetrate the thin portions of the patterned layer, as shown in FIG. 6C. The atom groups 618 strike the thick portions 632 forming impacted regions 622 of the patterned layer, and the thin portions 634 penetrating through to the magnetically susceptible layer 614 underneath, and implanting into the magnetically susceptible layer 614 to form implanted regions 628. The magnetic properties of the implanted regions 628 are altered by the implant, so the magnetically susceptible layer is patterned with magnetic and non-magnetic regions.

As described above, the atom groups may be ions or neutrals, and may be formed from large molecules or nanocondensates. The groups will generally be ionized to impart kinetic energy through electromagnetic forces. Once energized and directed toward the substrate, they may be neutralized by passing through a charge-exchange medium, such as an inert gas.

It should be noted that the energy required to modify the magnetic properties of the magnetically susceptible layer 614 is generally impact energy, which is derived from kinetic energy of the atom groups impacting the layer. The amount of energy required depends largely on the thickness of the layer. For a relatively thick layer 614, more modification of magnetic properties deeper into the substrate is required to yield a measurable different between treated and untreated areas. For a thin layer 614, however, a measureable difference may arise from modification of magnetic domains one or two deep beneath the surface. For thin layers, low energy treatment may be attractive, and energies may be so low that atoms from groups do not implant into the layer 614 but merely impact the layer 614. Groups may be imparted enough energy to penetrate the thin portions of the patterned layer with energy between that required to reorient magnetic domains near the surface and that required to implant into the surface. These groups may deposit on the surface of the substrate, or for very thin patterned layers, may rebound from the substrate surface. The groups may fragment upon impact, if the impact energy is higher than the cohesive energy or bond energy of the groups.

At 630, the patterned layer is removed from the substrate. This may be accomplished through an etching process, an ashing process, a cleaning process, or a physical abrasion process. If the patterned layer is a curable polymer, such as a carbon-containing layer, the patterned layer may be exposed to a reactive plasma. In another embodiment, the patterned layer may be etched by non-reactive ions. In yet another embodiment, the patterned layer may be removed by a chemical cleaning process, which may be a liquid exposure or vapor exposure process. FIG. 6D illustrates a substrate with a patterned magnetically susceptible layer 614 having treated areas 628 after the patterned layer is removed. The treated areas 628 have measurably different magnetic properties from the untreated areas.

At 640, a protective layer is formed over the substrate, substantially as described above. FIG. 6E shows a substrate with a protective layer 624 covering the magnetically susceptible layer 614 with the modified regions 628. At 650, a lubricating layer, substantially as described above, is formed on the substrate, as shown in FIG. 6F at 626.

Because detecting the difference in magnetic properties between the modified and unmodified regions becomes more difficult with distance, thickness of the protective layer 624 and lubricating layer 626 must be modulated to the overall specification of the substrate. As the area of the modified and unmodified regions shrinks, the magnitude difference in magnetic properties declines as well, so layers covering the magnetically susceptible layer must be made thinner to allow a read/write head to detect the different domains. In general, thickness of all layers covering the magnetically susceptible layer totals no more than about ten times the maximum width of the modified and unmodified regions of the magnetically susceptible layer. For a pattern resolution of 10 nm, for example, the thickness of layers covering the magnetically susceptible layer totals about 100 nm or less. In general, the thickness of the protective layer will be equal to or greater than the thickness of the lubricating layer. Thus, for example, if a substrate has a pattern resolution as small as 5 nm, the protective layer may have a thickness between about 30 nm and about 40 nm, while the lubricating layer has a thickness between about 10 nm and about 20 nm.

Embodiments of the invention may apply to, and incorporate, various types of magnetic recording media. For, example, recording media having a granular magnetic structure may be manufactured. Also, multi-layered magnetic thin films may be used. A magnetic thin film that is also a continuous magnetic film may be used with patterned media. The patterned media may be bit patterned media or track patterned media. In one embodiment, the magnetic thin film may be made of highly anisotropic magnetic material, suitable for a thermally assisted magnetic recording.

Methods disclosed herein may be used to generate magnetic substrates useable for magnetic recording media. Substrates formed according to the methods disclosed herein will have identifiable magnetic domains with dimension not larger than about 50 nm, such as between about 5 nm and about 50 nm, such as not more than about 25 nm, such as between about 5 nm and about 25 nm. The substrates will also have Rₐ surface roughness less than about 5 nm. Finally, the substrates will also comprise elements from the group consisting of boron, nitrogen, carbon, hydrogen, oxygen, silicon, germanium, fluorine, neon, argon, or xenon, by virtue of having been implanted with atom groups comprising one or more of these elements at doses between about 10¹⁴ and about 10¹⁶.

While the foregoing is directed to embodiments of the invention, other and further embodiments of the invention may be devised without departing from the basic scope thereof.

What is claimed is:

1. A method of forming a magnetic substrate, comprising:
modifying a magnetic property of a portion of a magnetically susceptible layer of the magnetic substrate by exposing the portion to atom groups, wherein the atom groups have energy selected to modify the magnetic property without substantially modifying the shape of the substrate surface.

2. The method of claim 1, wherein portions of the magnetically susceptible layer to be modified are identified by forming a patterned layer over the magnetically susceptible layer.

3. The method of claim 1, wherein the energy of the atom groups is higher than a lattice energy of the magnetically susceptible layer.

4. The method of claim 1, wherein the energy of the atom groups is selected to implant into the surface of the magnetically susceptible layer.

5. The method of claim 1, wherein the energy of the atom groups is selected to deposit on the surface of the magnetically susceptible layer without implanting into the surface.

6. The method of claim 1, wherein the energy of the atom groups is selected to rebound from the surface of the magnetically susceptible layer.

7. The method of claim 1, wherein the atom groups comprise boron, carbon, silicon, or germanium.

8. The method of claim 2, wherein the atom groups are ions having average energy less than about 50 keV.

9. The method of claim 8, wherein the ions are molecular ions.

10. The method of claim 1, wherein the atom groups are selected from the group consisting of boron hydride ions having at least 10 boron atoms, silicon hydride ions having at least 10 silicon atoms, germanium hydride ions having at least 10 germanium atoms, hydrocarbon ions having at least 10 carbon atoms, cluster ions, nanocondensate ions, neutralized species thereof, combinations thereof, or mixtures thereof.

11. The method of claim 2, wherein the atom groups are ions, and the atoms in the atom groups have average energy less than about 5 keV.

12. The method of claim 1, wherein the atom groups are propelled toward the magnetic recording medium.

13. The method of claim 2, wherein the atom groups are ions, and the atoms in the atom groups have average energy less than about 2 keV.

14. A method of treating a substrate, comprising:
forming a magnetically susceptible layer on a structural substrate;
forming a patterned layer over the magnetically susceptible layer to identify treatment zones and masked zones;
directing atom groups toward the substrate with energy sufficient to penetrate the patterned layer and implant into the treatment zones of the magnetically susceptible layer;
forming a protective layer over the substrate; and
forming a lubricating layer over the substrate.

15. The method of claim 14, wherein the atom groups are molecular ions, cluster ions, or neutralized species thereof, and the protective and lubricating layers have a total thickness less than about ten times an average maximum width of the treatment zones.

16. The method of claim 14, wherein implanting atom groups in the treatment zones reduces magnetic susceptibility of the treatment zones by at least 50%.

17. The method of claim 16, wherein implanting atom groups into the treatment zones increases Ra roughness of the substrate surface by less than 1 nm.

18. The method of claim 14, wherein forming the patterned layer over the magnetically susceptible layer comprises applying a pattern material over the magnetically susceptible layer, physically transferring a pattern into the pattern layer, and at least partially curing the pattern layer to form the patterned layer with a desired hardness.

19. The method of claim 18, wherein hardening agents are added to the pattern material to reach the desired hardness upon curing.

20. An apparatus for manufacturing magnetic storage media, comprising:
a source of large atom groups;
coupled to the source of large atom groups, an ion beam generator for generating large ions from the large atom groups; and
a substrate support comprising a plurality of substrate sites, wherein the substrate support can move with respect to the ion beam generator, or the ion beam generator can move with respect to the substrate support.

21. The apparatus of claim 20, further comprising a neutralizer disposed between the ion beam generator and the movable substrate support.

22. A substrate having a magnetically susceptible layer comprising identifiable magnetic domains having dimension not larger than about 50 nm, and cobalt regions implanted with one or more elements from the group consisting of boron, nitrogen, oxygen, carbon, hydrogen, fluorine, silicon, germanium, neon, argon, and xenon.

23. The substrate of claim 22, wherein the magnetic domains have dimension not larger than about 25 nm.

24. A substrate having a magnetically susceptible layer comprising identifiable magnetic domains having dimension not larger than about 50 nm, wherein a surface of the substrate has Rₐ surface roughness less than about 5 nm.

25. The substrate of claim 24, wherein the magnetic domains have dimension not larger than about 25 nm.
